(19) United States
(12) Patent Application Publication
(10) Pub. No.: US 2013/0177128 A1
(43) Pub. Date: Jul. 11, 2013

(54) SHIFT REGISTER AND METHOD THEREOF

(71) Applicants: Chien-Chuan Ko, New Taipei (TW); Chao-Hui Wu, New Taipei (TW)

(72) Inventors: Chien-Chuan Ko, New Taipei (TW); Chao-Hui Wu, New Taipei (TW)

(73) Assignee: HANNSTAR DISPLAY CORP., New Taipei (TW)

(21) Appl. No.: 13/525,892

(22) Filed: Jun. 18, 2012

(30) Foreign Application Priority Data
Jan. 11, 2012 (CN) 201210007689.1

(51) Int. Cl. G11C 19/28

(52) U.S. Cl. 377/64

(57) ABSTRACT

Shift register and method thereof are provided. The proposed shift register includes a first to a third transistors, each of which has a first terminal, a second terminal and a control terminal, wherein the second terminal of the first transistor, the control terminal of the second transistor and the first terminal of the third transistor are electrically connected to a node, and the first terminal of the first transistor is electrically connected to the control terminal of the first transistor.

### CROSS-REFERENCES TO RELATED APPLICATIONS

The application claims the benefit of Chinese Patent Application No. 201210007689.1 filed on Jan. 11, 2012, in the State IPO of the PRC, the disclosures of which are incorporated herein in their entirety by reference.

### FIELD OF THE INVENTION

The present invention relates to a shift register. More particularly, it relates to a shift register disposed on a glass substrate.

### BACKGROUND OF THE INVENTION

A technology, which combines the scan driver (also named gate driver in general) with the glass substrate there below and employs the thin film transistor (TFT) process to produce so as to achieve a higher resolution and to decrease production costs, is widely used and is successfully realized in the amorphous silicon thin film transistor process with N-type transistor. The functions of the scan driver are realized via a shift register. FIG. 1 shows a gate driver circuit of Samsung Korea, published in year 2008 (US Patent Application No. 20080100560), it includes a pull-up part 211, a pull-down part 213, a pull-up driving part 214, a ripple preventing part 215, a holding part 216, an inverter 217 and a reset part 218. The aforementioned gate driver circuit can reach a quite good compensation effect since the coupling effect caused by CK1 in the circuit in an off-state period (the period where the gate is kept at V_{gl}) is completely curbed. Many TFTs are used during this period to engage in the discharging actions. Since the forced to discharge scheme is used, the static state power consumption is higher during the off-state period. Besides, the off-state period is far more larger than the real operational time of the circuit (the time to charge the gate line to Vgh and then to discharge the gate line to Vgl), the power consumption of the whole circuit is high when the static state power consumption of the circuit during the off-state period is high, and this is a drawback of the integrated gate driver (IGD) in the prior art. In summary, the shift register in the prior art has two drawbacks that the static state power consumption of the circuit is too large and the circuit is far more complex.

Keeping the drawbacks of the prior arts in mind, and employing experiments and research full-heartily and persistently, the applicant finally conceived a shift register and a method thereof.

### SUMMARY OF THE INVENTION

It is therefore an object of the present invention to provide a shift register having a more concise circuit and the static state power consumption thereof is dramatically decreased.

According to the first aspect of the present invention, a shift register disposed on a glass substrate comprises a first thin film transistor (TFT) including a first terminal receiving one of a start-up pulse and a (N−1)-th stage pulse, a second terminal, and a control terminal, a second TFT including a first terminal receiving a time pulse signal, a second terminal outputting an Nth stage pulse, and a control terminal electrically connected to the second terminal of the first TFT, a capacitor having a first terminal electrically connected to the control terminal of the second TFT, and a second terminal electrically connected to the second terminal of the second TFT, and a third TFT including a first terminal electrically connected to the first terminal of the capacitor at a first node, a second terminal receiving a common ground voltage, and a control terminal receiving a (N+2)-th stage pulse.

According to the second aspect of the present invention, a shift register disposed on a glass substrate comprises a first to a third transistors, each of which has a first terminal, a second terminal and a control terminal, wherein the second terminal of the first transistor, the control terminal of the second transistor and the first terminal of the third transistor are electrically connected to a first node.

According to the third aspect of the present invention, an operating method for a shift register disposed on a glass substrate, wherein the shift register includes a first to a third transistors, each of which has a first terminal, a second terminal and a control terminal, the second terminal of the first transistor, the control terminal of the second transistor and the first terminal of the third transistor are electrically connected to a first node having a first node potential, the first terminal of the first transistor receives one of a start-up pulse and a (N−1)-th stage pulse, a first terminal of the second transistor receives a time pulse signal, and the control terminal of the third transistor receives a (N+2)-th stage pulse, comprises steps of: using the (N−1)-th stage pulse to pre-charge the first node; when the time pulse signal raises to a first potential, raising the first node potential to a relatively high value via a capacitance coupling effect; causing a gate line passing through the second transistor to engage in an action of being charged to the first potential, within a frame time; when the time pulse signal drops from the first potential to a second potential, causing the gate line to engage in an action of being discharged to the second potential, within the frame time; and using the (N+2)-th stage pulse to discharge the first node potential to a common ground voltage.

The present invention may best be understood through the following descriptions with reference to the accompanying drawings, in which:

### BRIEF DESCRIPTION OF THE DRAWINGS

FIG. 1 is a circuit diagram of a gate driver circuit in the prior art;

FIG. 2 is a circuit diagram of a shift register according to the first preferred embodiment of the present invention;

FIG. 3 is an operational waveform diagram of a shift register according to the first preferred embodiment of the present invention;

FIG. 4 is a circuit diagram of a shift register according to the second preferred embodiment of the present invention; and

FIG. 5 is an operational waveform diagram of a shift register according to the second preferred embodiment of the present invention.

### DETAILED DESCRIPTION OF THE PREFERRED EMBODIMENT

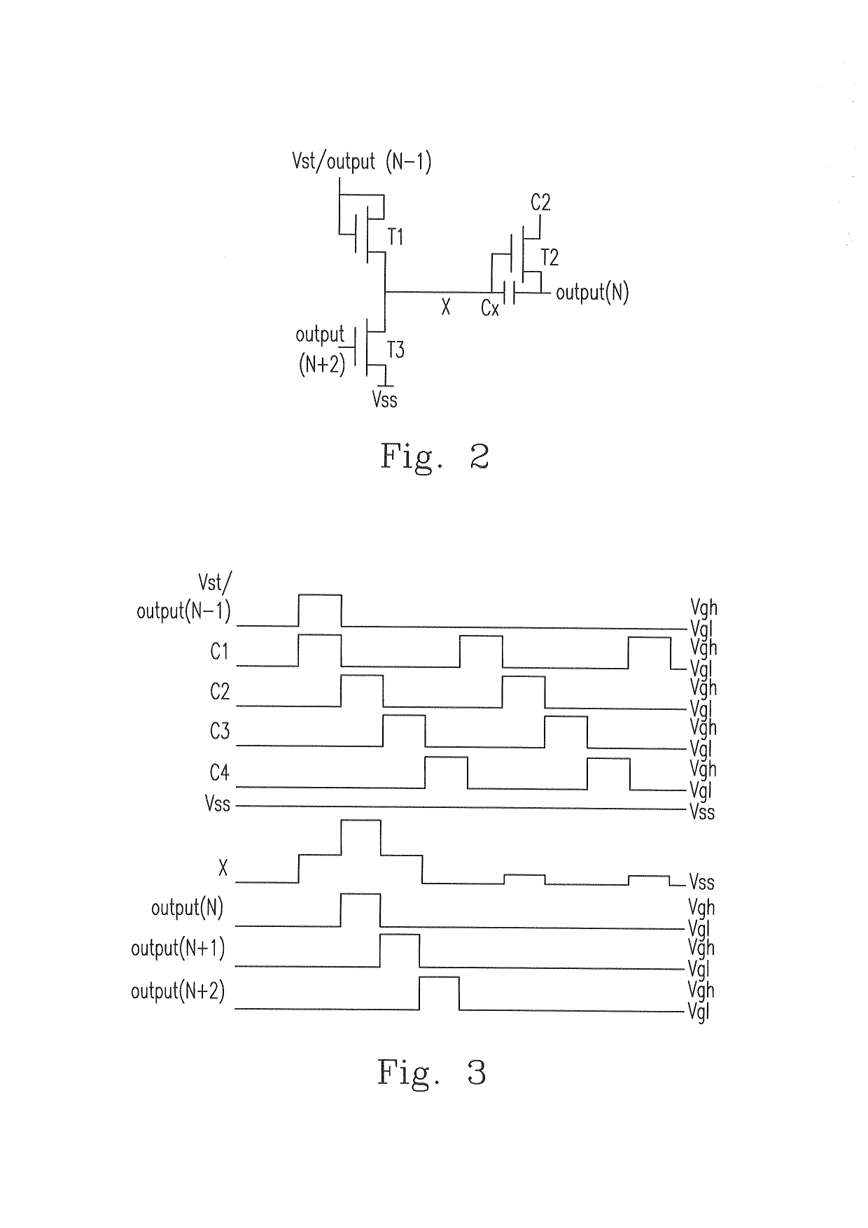

The present invention provides a shift register as shown in FIG. 2, and three TFTs: T1-T3 and a capacitor Cx are used in total, wherein T1 uses the (N−1)-th stage pulse of the previous stage to precharge the node X, and then the time pulse signal C2 (time pulse 2, Clock 2) is raised to Vgh. After the X node is coupled to a higher potential due to the influence of the capacitive coupling effect, T2 is in charge of engaging in an action of charging the gate line to a first potential (Vgh) in a frame time. After that, the time pulse signal C2 decreases from Vgh to a second potential Vgl, T2 engages in an action of discharging the gate line to Vgl in a frame time, and then T3 uses the (N+2)-th stage (the next-next stage) pulse to discharge the X node to ground voltage Vss (its potential is lower than Vgl). The corresponding operational waveforms are shown in FIG. 3, wherein the time pulse signals are C1-C4. For example, when C2 (time pulse 2, Clock 2) is the time pulse signal of the Nth stage shift register, then C1, C3 and C4 are the time pulse signals of shift registers of another three stages (the (N−1)-th stage, the (N+1)-th stage and the (N+2)-th stage respectively). And, Vst/output (N−1) is a start-up pulse or a (N−1)-th stage pulse.

In the off-state period of the circuit, even if the node X is influenced by the coupling effect of C2 (time pulse 2, Clock 2) towards the capacitor, T2 is not allowed to generate a large enough conduction current to charge the gate line due to that the node X is discharged to be lower than the source of T1 (kept at Vgl).

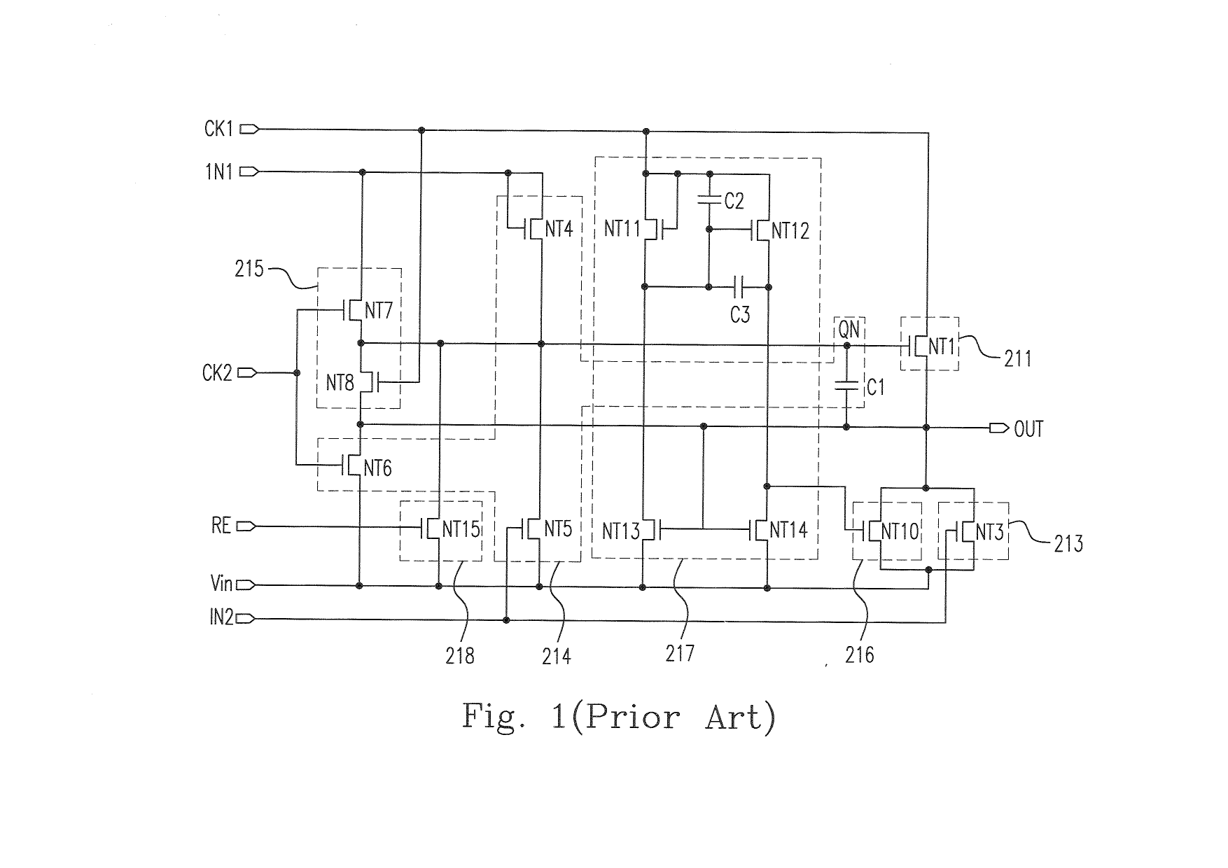

According to the real Hspice simulation results, a static state current consumption of the shift register circuit of Samsung as shown in FIG. 1 is 3.987 μA, and a static state current consumption of the new shift register proposed in the present invention (see FIG. 2) is only 1.142 μA.

Due to that both of the gate source voltages of T1 and T3 are larger than zero (since Vgl is higher than Vss), there is a leakage route discharging via C2 (Vgl˜Vgh) and through T2 of the Nth stage to generate the output (N), and then discharging via T1 and T3 of the (N+1)-th stage to generate Vss.

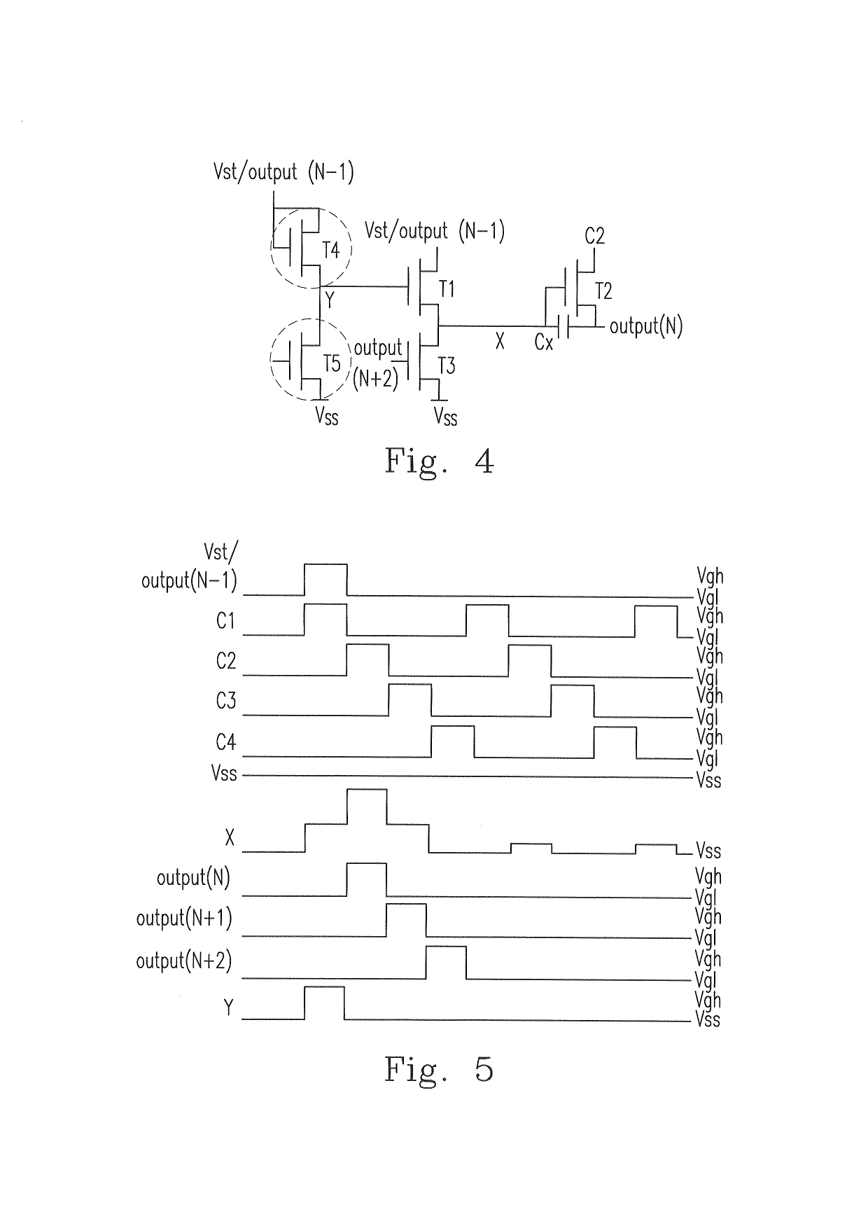

To further decrease the static state power consumption of the IGD circuit in the off-state period, the second preferred embodiment of the present invention has two extra smaller TFTs: T4 and T5 (since the load capacitors pushed by them are small, no large size is required) to let the gate node Y of T1 be discharged to Vss in the off-state period such that the Vgs of T1 will be decreased to approach 0V (as shown in FIG. 4). The operational waveforms of the above-mentioned second preferred embodiment of the present invention are shown in FIG. 5.

According to the real Hspice simulation results, the static state current consumption of the circuit can be further decreased from the original 1.142 μA to 0.54 μA.

### Embodiments

1. A shift register disposed on a glass substrate, comprising:

a first thin film transistor (TFT) including:

a first terminal receiving one of a start-up pulse and a (N−1)-th stage pulse;

a second terminal; and

a control terminal;

a second TFT including:

a first terminal receiving a time pulse signal;

a second terminal outputting an Nth stage pulse; and

a control terminal electrically connected to the second terminal of the first TFT;

a capacitor having a first terminal electrically connected to the control terminal of the second TFT, and a second terminal electrically connected to the second terminal of the second TFT; and

a third TFT including:

a first terminal electrically connected to the first terminal of the capacitor at a first node;

a second terminal receiving a common ground voltage; and

a control terminal receiving a (N+2)-th stage pulse.

2. A shift register according to embodiment 1, wherein the control terminal of the first TFT is electrically connected to the first terminal of the first TFT.

3. A shift register according to embodiment 1 or 2 further comprising:

a fourth TFT including:

a first terminal receiving the one of the start-up pulse and the (N−1)-th stage pulse;

a second terminal electrically connected to the control terminal of the first TFT; and

a control terminal electrically connected to the first terminal of the fourth TFT; and

a fifth TFT including:

a first terminal electrically connected to the second terminal of the fourth TFT at a second node;

a second terminal receiving the common ground voltage; and

a control terminal receiving the time pulse signal.

4. A shift register disposed on a glass substrate, comprising a first to a third transistors, each of which has a first terminal, a second terminal and a control terminal, wherein the second terminal of the first transistor, the control terminal of the second transistor and the first terminal of the third transistor are electrically connected to a first node.

5. A shift register according to embodiment 4, wherein the first terminal of the first transistor is electrically connected to the control terminal of the first transistor.

6. A shift register according to embodiment 4 or 5 further comprising a capacitor, wherein the capacitor has a first terminal electrically connected to the control terminal of the second transistor, and a second terminal electrically connected to the second terminal of the second transistor, the first terminal of the first transistor receives one of a start-up pulse and a (N−1)-th stage pulse, the first terminal of the second transistor receives a time pulse signal, the control terminal of the third transistor receives a (N+2)-th stage pulse, and the second terminal of the third transistor receives a common ground voltage.

7. A shift register according to embodiments 4 or 6 further comprising:

a fourth transistor including:

a first terminal receiving one of the start-up pulse and the (N−1)-th stage pulse;

a second terminal electrically connected to the control terminal of the first transistor; and

a control terminal electrically connected to the first terminal of the fourth transistor; and

a fifth transistor including:

a first terminal electrically connected to the second terminal of the fourth transistor at a second node;

a second terminal receiving the common ground voltage; and

a control terminal receiving the time pulse signal.

8. A shift register according to any one of embodiments 4 to 7, wherein each of the first to the fifth transistors is a TFT.

9. An operating method for a shift register disposed on a glass substrate, wherein the shift register includes a first to a third transistors, each of which has a first terminal, a second terminal and a control terminal, the second terminal of the first transistor, the control terminal of the second transistor and the first terminal of the third transistor are electrically connected to a first node having a first node potential, the first terminal of the first transistor receives one of a start-up pulse and a (N−1)-th stage pulse, a first terminal of the second transistor receives a time pulse signal, and the control terminal of the third transistor receives a (N+2)-th stage pulse, the method comprising steps of:

causing the (N−1)-th stage pulse to pre-charge the first node;

when the time pulse signal raises to a first potential, raising the first node potential to a relatively high value via a capacitance coupling effect;

causing a gate line passing through the second transistor to engage in an action of being charged to the first potential, within a frame time;

when the time pulse signal drops from the first potential to a second potential, causing the gate line to engage in an action of being discharged to the second potential, within the frame time; and

using the (N+2)-th stage pulse to discharge the first node potential to a common ground voltage.

10. A method according to embodiment 9, wherein the second terminal of the second transistor is used to output an Nth stage pulse, and there is a leakage route discharging from the first terminal of the second transistor via the time pulse signal to the first terminal of the second transistor to generate the Nth stage pulse, and then discharging from the first transistor to the third transistor to generate the common ground voltage.

11. A method according to embodiment 9 or 10, wherein each of the first to the third transistors is a TFT.

12. A method according to any one of embodiments 9 to 11, wherein the first, the second and the control terminals are a drain, a source and a gate respectively.

13. A method according to any one of embodiments 9 to 12, wherein the first potential is a gate high potential, and the second potential is a gate low potential.

14. A method according to any one of embodiments 9 to 13, wherein respective gate source voltages of the first and the third transistors are both larger than zero.

15. A method according to any one of embodiments 9 to 14, wherein the first terminal of the first transistor is electrically connected to the control terminal of the first transistor.

16. A method according to any one of embodiments 9 to 14, wherein the shift register further includes a fourth and a fifth transistors, each of which has a first, a second and a control terminals, the second terminal of the fourth transistor is electrically connected to the control terminal of the first transistor, the first terminal of the fourth transistor receives the one of a start-up pulse and a (N−1)-th stage pulse, and is electrically connected to the control terminal of the fourth transistor, the first terminal of the fifth transistor is electrically connected to the second terminal of the fourth TFT at a second node having a second node potential, the control terminal of the fifth transistor receives the time pulse signal, the second terminal of the fifth transistor receives the common ground voltage, and the method further comprises a step of causing the second node potential to be discharged to the common ground voltage to let the gate source voltage of the first transistor decrease to approach zero in a off-state period.

17. A method according to any one of embodiments 9 to 16, wherein each of the fourth and the fifth transistors is a TFT, and the first, the second and the control terminals of one of the fourth and the fifth transistors are a drain, a source and a gate respectively.

According to the aforementioned descriptions, the present invention provides a shift register having a more concise circuit and the static state power consumption thereof is dramatically decreased so as to possess the non-obviousness and the novelty.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A shift register disposed on a glass substrate, comprising:
a first thin film transistor (TFT) including:
a first terminal receiving one of a start-up pulse and a (N−1)-th stage pulse;
a second terminal; and
a control terminal;
a second TFT including:
a first terminal receiving a time pulse signal;
a second terminal outputting an Nth stage pulse; and
a control terminal electrically connected to the second terminal of the first TFT;
a capacitor having a first terminal electrically connected to the control terminal of the second TFT, and a second terminal electrically connected to the second terminal of the second TFT; and
a third TFT including:
a first terminal electrically connected to the first terminal of the capacitor at a first node;
a second terminal receiving a common ground voltage; and
a control terminal receiving a (N+2)-th stage pulse.

2. A shift register according to claim 1, wherein the control terminal of the first TFT is electrically connected to the first terminal of the first TFT.

3. A shift register according to claim 1 further comprising:
a fourth TFT including:
a first terminal receiving the one of the start-up pulse and the (N−1)-th stage pulse;
a second terminal electrically connected to the control terminal of the first TFT; and
a control terminal electrically connected to the first terminal of the fourth TFT; and
a fifth TFT including:
a first terminal electrically connected to the second terminal of the fourth TFT at a second node;
a second terminal receiving the common ground voltage; and
a control terminal receiving the time pulse signal.

4. A shift register disposed on a glass substrate, comprising a first to a third transistors, each of which has a first terminal, a second terminal and a control terminal, wherein the second terminal of the first transistor, the control terminal of the second transistor and the first terminal of the third transistor are electrically connected to a first node.

5. A shift register according to claim 4, wherein the first terminal of the first transistor is electrically connected to the control terminal of the first transistor.

6. A shift register according to claim 4 further comprising a capacitor, wherein the capacitor has a first terminal electrically connected to the control terminal of the second transistor, and a second terminal electrically connected to the second terminal of the second transistor, the first terminal of the first transistor receives one of a start-up pulse and a (N−1)-th stage pulse, the first terminal of the second transistor receives a time pulse signal, the control terminal of the third transistor receives a (N+2)-th stage pulse, and the second terminal of the third transistor receives a common ground voltage.

7. A shift register according to claim 6 further comprising:
a fourth transistor including:
a first terminal receiving one of the start-up pulse and the (N−1)-th stage pulse;
a second terminal electrically connected to the control terminal of the first transistor; and
a control terminal electrically connected to the first terminal of the fourth transistor; and
a fifth transistor including:
a first terminal electrically connected to the second terminal of the fourth transistor at a second node;
a second terminal receiving the common ground voltage; and
a control terminal receiving the time pulse signal.

8. A shift register according to claim 7, wherein each of the first to the fifth transistors is a TFT.

9. An operating method for a shift register disposed on a glass substrate, wherein the shift register includes a first to a third transistors, each of which has a first terminal, a second terminal and a control terminal, the second terminal of the first transistor, the control terminal of the second transistor and the first terminal of the third transistor are electrically connected to a first node having a first node potential, the first terminal of the first transistor receives one of a start-up pulse and a (N−1)-th stage pulse, a first terminal of the second transistor receives a time pulse signal, and the control terminal of the third transistor receives a (N+2)-th stage pulse, the method comprising steps of:
using the (N−1)-th stage pulse to pre-charge the first node;
when the time pulse signal raises to a first potential, raising the first node potential to a relatively high value via a capacitance coupling effect;
causing a gate line passing through the second transistor to engage in an action of being charged to the first potential, within a frame time;
when the time pulse signal drops from the first potential to a second potential, causing the gate line to engage in an action of being discharged to the second potential, within the frame time; and
using the (N+2)-th stage pulse to discharge the first node potential to a common ground voltage.

10. A method according to claim 9, wherein the second terminal of the second transistor is used to output an Nth stage pulse, and there is a leakage route discharging from the first terminal of the second transistor via the time pulse signal to the first terminal of the second transistor to generate the Nth stage pulse, and then discharging from the first transistor to the third transistor to generate the common ground voltage.

11. A method according to claim 9, wherein each of the first to the third transistors is a TFT.

12. A method according to claim 9, wherein the first, the second and the control terminals are a drain, a source and a gate respectively.

13. A method according to claim 9, wherein the first potential is a gate high potential, and the second potential is a gate low potential.

14. A method according to claim 9, wherein respective gate source voltages of the first and the third transistors are both larger than zero.

15. A method according to claim 9, wherein the first terminal of the first transistor is electrically connected to the control terminal of the first transistor.

16. A method according to claim 9, wherein the shift register further includes a fourth and a fifth transistors, each of which has a first, a second and a control terminals, the second terminal of the fourth transistor is electrically connected to the control terminal of the first transistor, the first terminal of the fourth transistor receives the one of a start-up pulse and a (N−1)-th stage pulse, and is electrically connected to the control terminal of the fourth transistor, the first terminal of the fifth transistor is electrically connected to the second terminal of the fourth TFT at a second node having a second node potential, the control terminal of the fifth transistor receives the time pulse signal, the second terminal of the fifth transistor receives the common ground voltage, and the method further comprises a step of causing the second node potential to be discharged to the common ground voltage to let the gate source voltage of the first transistor decrease to approach zero in a off-state period.

17. A method according to claim 16, wherein each of the fourth and the fifth transistors is a TFT, and the first, the second and the control terminals of one of the fourth and the fifth transistors are a drain, a source and a gate respectively.
